(19) United States
(12) Patent Application Publication
(10) Pub. No.: US 2025/0372495 A1
(43) Pub. Date: Dec. 4, 2025

(54) ELECTRONIC PACKAGE AND MANUFACTURING METHOD THEREOF AND INTERPOSER

(71) Applicant: SILICONWARE PRECISION INDUSTRIES CO., LTD., Taichung City (TW)

(72) Inventor: Yung-Ta LI, Taichung City (TW)

(21) Appl. No.: 18/768,805

(22) Filed: Jul. 10, 2024

(30) Foreign Application Priority Data
May 28, 2024 (TW) 113119722

(51) Int. Cl. H01L 23/498; H01L 21/48; H01L 23/31; H01L 25/065

(52) U.S. Cl. CPC H01L 23/49838; H01L 21/4853; H01L 21/4857; H01L 23/3135; H01L 23/49811; H01L 23/49822; H01L 25/0655

(57) ABSTRACT

An electronic package and a manufacturing method thereof and an interposer are provided, in which grooves are formed on conductive through holes on a back side of an interposer body of the interposer, and a routing structure electrically connected to the conductive through holes is formed directly on the back side of the interposer body and in the grooves, without a passivation layer to be formed, such that the CVD process and CMP process are omitted, thereby effectively simplifying the manufacturing process and saving a lot of manufacturing time and material costs.

### CROSS-REFERENCE TO RELATED APPLICATIONS

The present application is based upon and claims the right of priority to TW patent application No. 113119722, filed May 28, 2024, the disclosure of which is hereby incorporated by reference herein in its entirety for all purposes.

### BACKGROUND

### 1. Technical Field

The present disclosure relates to a semiconductor packaging technology, and more particularly, to an electronic package and a manufacturing method thereof and an interposer that can reduce costs.

### 2. Description of Related Art

With the vigorous development of the electronics industry, electronic products are gradually developing toward the trend of multi-functionality and high performance. Therefore, the semiconductor industry is not only continuing to develop advanced processes, but is also seeking ways to keep chips small while maintaining high performance. As a result, “heterogeneous integration” has become a prominent concept in today's world, and chips have also evolved from single-layer in prior art to multi-layer stacked in advance packaging.

FIG. 1A to FIG. 1E are schematic cross-sectional views illustrating a manufacturing method of a conventional silicon interposer 1 for chip stacking.

As shown in FIG. 1A, a silicon board 10 having a first side 10a and a second side 10b opposing the first side 10a is provided, in which a plurality of conductive through-silicon vias (TSVs) 100 consisting of insulating materials 101 and conductive materials 102 (e.g., copper materials) are formed. A passivation layer 11 is formed on the first side 10a, and a redistribution layer (RDL) 12 electrically connected to the conductive TSVs 100 is formed on the passivation layer 11. Then, an insulating protective layer 13 is formed on the passivation layer 11 and the RDL 12, and parts of the RDL 12 are exposed out from the insulating protective layer 13 for a plurality of copper bumps 14 to be bonded to the exposed surfaces of the RDL 12. Thereafter, a temporary carrier 5 (e.g., made of glass) is bonded to the insulating protective layer 13 at the first side 10a via an adhesive 50, so that the copper bumps 14 are embedded into the adhesive 50. Then, part of material of the second side 10b of the silicon board 10 is removed by grinding and wet etching so that the conductive materials 102 of the conductive TSVs 100 protrude out from the second side 10b.

As shown in FIG. 1B, another passivation layer 15 is formed on the second side 10b by means of chemical vapor deposition (CVD) to cover the protruding conductive materials 102.

As shown in FIG. 1C, the passivation layer 15 and the protruding conductive materials 102 are ground by means of chemical mechanical polishing (CMP) so that end surfaces of the conductive TSVs 100 are flush with a surface of the passivation layer 15.

As shown in FIG. 1D, an RDL process is performed on the passivation layer 15 to form a routing structure 16. The routing structure 16 includes an insulating layer 160 formed on the silicon board 10, and a routing layer 161 formed on the insulating layer 160. A plurality of solder bumps 17 having micro bump (u-bump) specification are bonded to the routing layer 161.

As shown in FIG. 1E, the temporary carrier 5 and the adhesive 50 are removed.

However, in the manufacturing method of the conventional silicon interposer 1, the CVD process and CMP process are required to manufacture the silicon interposer 1, which needs a large amount of process time and material cost (e.g., another passivation layer 15), resulting in a substantial increase in the manufacturing cost.

Therefore, how to overcome the various problems of the above-mentioned prior art has become an urgent issue to be solved.

### SUMMARY

In view of the various deficiencies of the prior art, the present disclosure provides an interposer, which comprises: an interposer body having a first side, a second side opposing the first side, a plurality of conductive through holes formed in the interposer body, and a plurality of grooves formed on the second side of the interposer body and corresponding to the plurality of conductive through holes; and a routing structure disposed on the second side of the interposer body, extending into the plurality of grooves, and electrically connected to the plurality of conductive through holes.

The present disclosure also provides an electronic package, which comprises: an interposer body having a first side, a second side opposing the first side, a plurality of conductive through holes formed in the interposer body, and a plurality of grooves formed on the second side of the interposer body and corresponding to the plurality of conductive through holes; a routing structure disposed on the second side of the interposer body, extending into the plurality of grooves, and electrically connected to the plurality of conductive through holes; a circuit structure disposed on the first side of the interposer body and electrically connected to the plurality of conductive through holes; and an electronic component disposed on and electrically connected to the circuit structure.

The aforementioned electronic package further comprises an encapsulation layer covering the interposer body and having a first surface and a second surface opposing the first surface, wherein the circuit structure is disposed on the first surface of the encapsulation layer. For example, the aforementioned electronic package further comprises a circuit portion disposed on the second surface of the encapsulation layer and electrically connected to the plurality of conductive through holes. Furthermore, the circuit portion is bonded with a plurality of conductive bumps.

Alternatively, the aforementioned electronic package further comprises a plurality of conductive pillars formed in the encapsulation layer and electrically connected to the circuit structure. For example, the plurality of conductive pillars are formed with further grooves, and the routing structure extends to the further grooves to electrically connect to the plurality of conductive pillars.

Or, the routing structure is bonded with a plurality of conductive elements.

The present disclosure also provides a method of manufacturing an electronic package, the method comprises: providing an interposer body having a first side, a second side opposing the first side, and a plurality of conductive through holes formed in the interposer body; forming a plurality of grooves on the second side of the interposer body and corresponding to the plurality of conductive through holes; forming a routing structure on the second side of the interposer body in a manner that the routing structure extends into the plurality of grooves and is electrically connected to the plurality of conductive through holes; and disposing the interposer body on a circuit portion with a plurality of conductive pillars via the second side thereof, and electrically connecting the routing structure to the circuit portion via a plurality of conductive elements.

The aforementioned method further comprises forming an encapsulation layer on the circuit portion to cover the interposer body and the routing structure, and forming a circuit structure on the encapsulation layer and the first side of the interposer body to be electrically connected to the plurality of conductive through holes. The aforementioned method further comprises disposing an electronic component on the circuit structure and electrically connecting the electronic component to the circuit structure.

The aforementioned method further comprises forming a plurality of conductive bumps on the circuit portion.

The present disclosure also provides a method of manufacturing an electronic package, the method comprises: providing an interposer body having a first side, a second side opposing the first side, and a plurality of conductive through holes formed in the interposer body; forming a circuit structure on the first side of the interposer body to be electrically connected to the plurality of conductive through holes; disposing an electronic component on the circuit structure and electrically connecting the electronic component to the circuit structure; forming a plurality of grooves on the second side of the interposer body and corresponding to the plurality of conductive through holes; and forming a routing structure on the second side of the interposer body in a manner that the routing structure extends into the plurality of grooves and is electrically connected to the plurality of conductive through holes.

The aforementioned method further comprises forming an encapsulation layer to cover the interposer body, and forming the circuit structure on the encapsulation layer and the first side of the interposer body. The aforementioned method further comprises forming a plurality of conductive pillars in the encapsulation layer and electrically connecting the plurality of conductive pillars to the circuit structure. In the aforementioned method, the plurality of conductive pillars are formed with further grooves, and the routing structure extends to the further grooves to electrically connect to the plurality of conductive pillars.

In the aforementioned method, the routing structure is bonded with a plurality of conductive elements.

In the aforementioned electronic package, methods and interposer, the first side of the interposer body is formed with a redistribution layer electrically connected to the plurality of conductive through holes.

As can be seen from the above, the electronic package and manufacturing method thereof and interposer involves the formation of grooves on the conductive through holes, and the routing structure is directly formed on the grooves and the second side of the interposer body, so a passivation layer does not need to be formed, thus obviating the CVD process and CMP process. Accordingly, in comparison to the prior art, the electronic package of the present disclosure can effectively simplify the manufacturing process and save a lot of manufacturing time and material costs, thereby significantly reducing the manufacturing cost.

### BRIEF DESCRIPTION OF THE DRAWINGS

FIG. 1A to FIG. 1E are schematic cross-sectional views illustrating a manufacturing method of a conventional silicon interposer.

FIG. 2A to FIG. 2F-1 and FIG. 2G to FIG. 2I are schematic cross-sectional views illustrating a manufacturing method of an electronic package according to the first embodiment of the present disclosure.

FIG. 2F-2 is a schematic cross-sectional view of another aspect of FIG. 2F-1.

FIG. 3A to FIG. 3F are schematic cross-sectional views illustrating a manufacturing method of an electronic package according to the second embodiment of the present disclosure.

### DETAILED DESCRIPTION

Embodiments of the present disclosure are described below with specific examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one” and the like are merely for clear explanation rather than limiting the practicable scope of the present disclosure, and thus, alterations or adjustments of the relative relationships thereof without essentially altering the technical contents should still be considered in the practicable scope of the present disclosure.

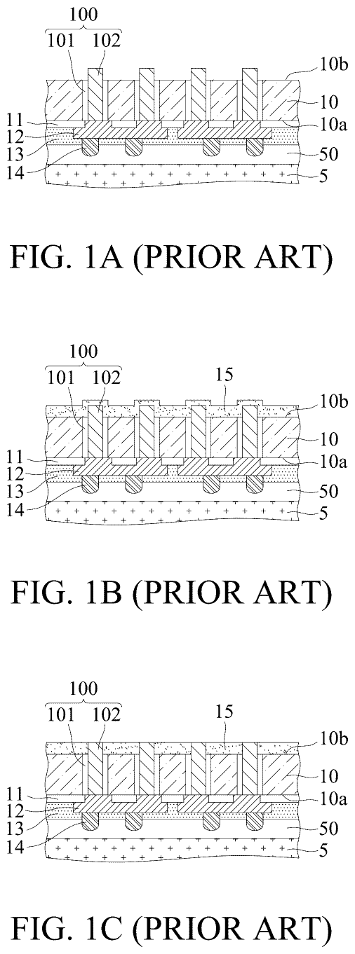

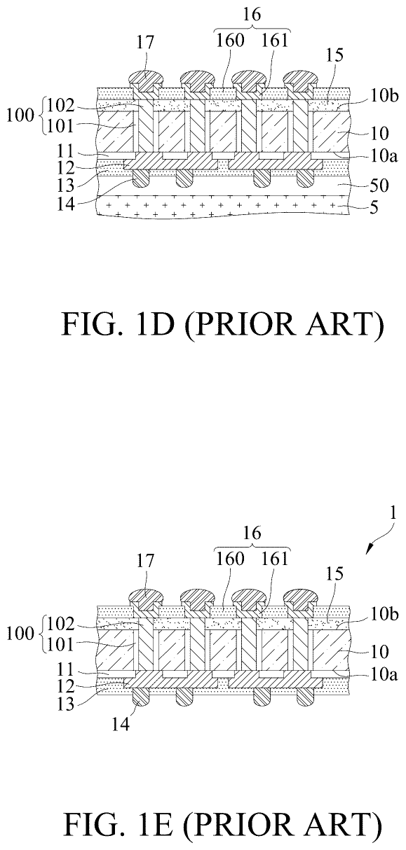

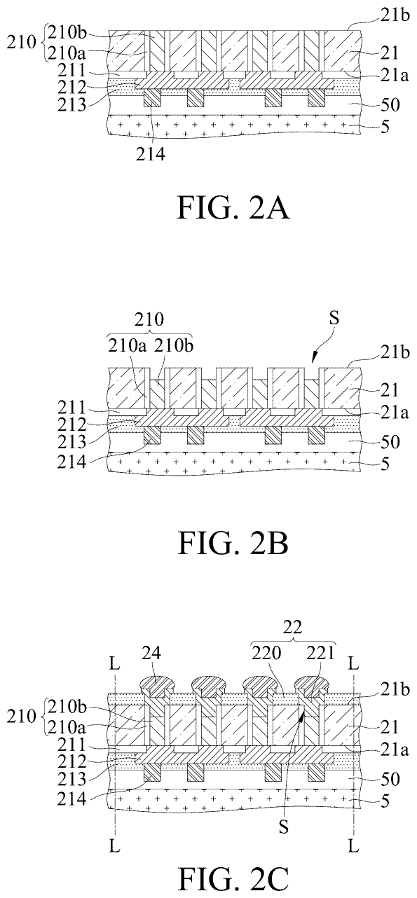

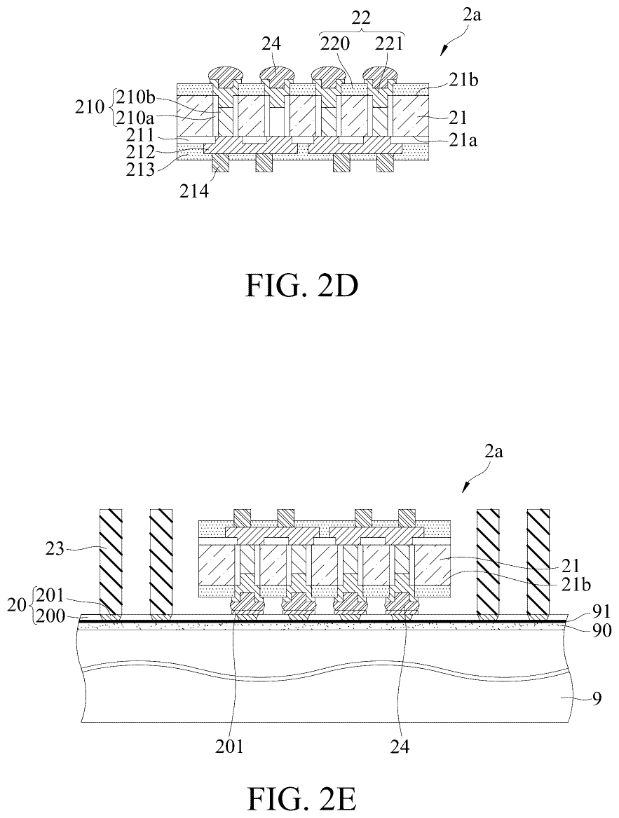

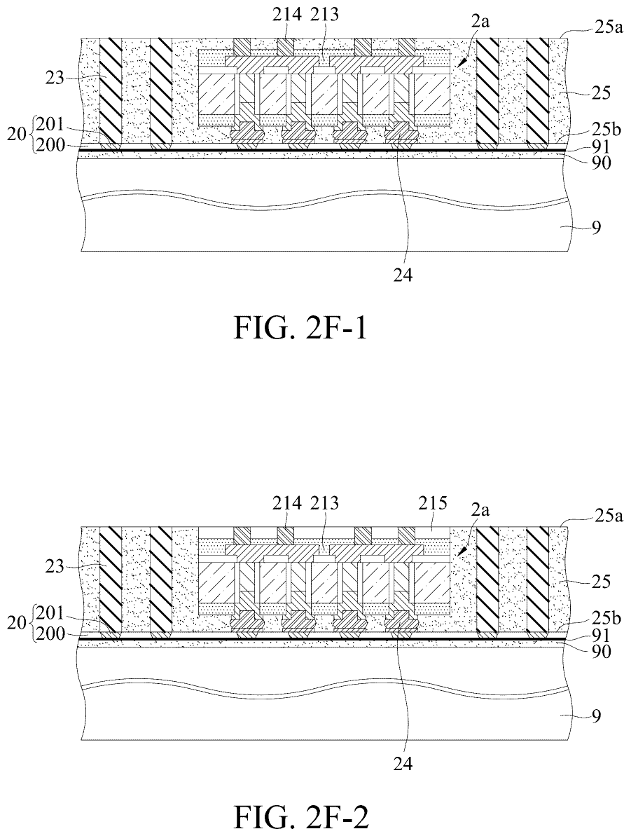

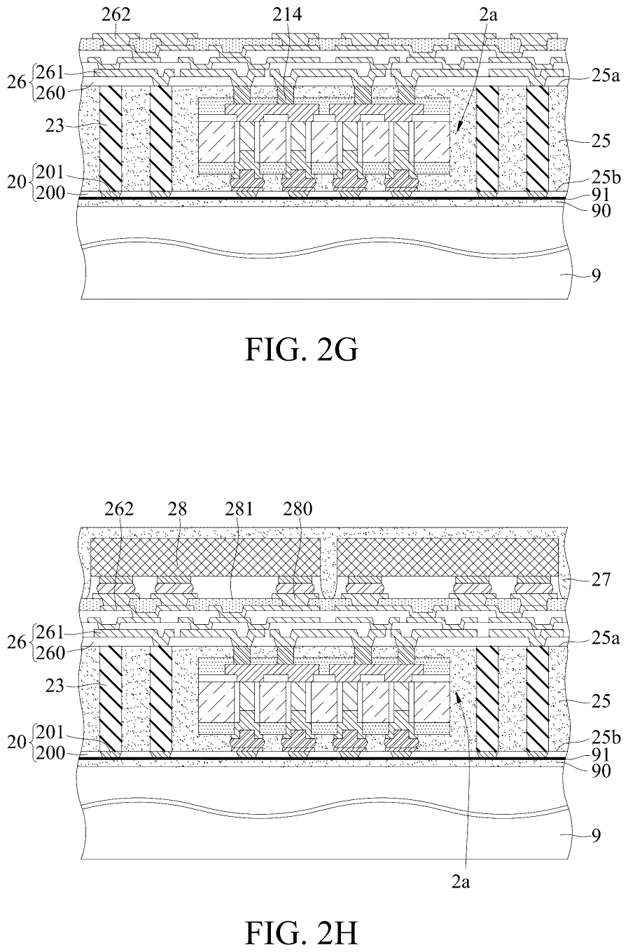

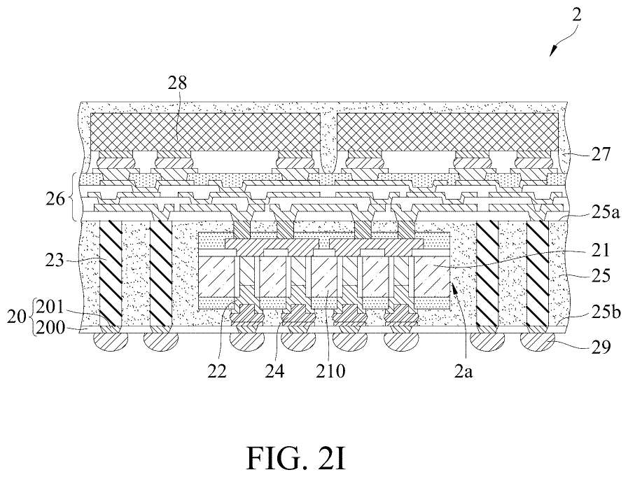

FIG. 2A to FIG. 2F-1 and FIG. 2G to FIG. 2I are schematic cross-sectional views illustrating a manufacturing method of an electronic package 2 according to the first embodiment of the present disclosure.

As shown in FIG. 2A, an interposer body 21 having a first side 21a and a second side 21b opposing the first side 21a is provided, in which a plurality of conductive through holes 210 consisting of insulating materials 210a and conductive materials 210b are formed. A passivation layer 211 is formed on the first side 21a, a redistribution layer (RDL) 212 electrically connected to the conductive through holes 210 is formed on the passivation layer 211, an insulating protective layer 213 is formed on the passivation layer 211 and the RDL 212, and parts of the RDL 212 are exposed out from the insulating protective layer 213 for a plurality of conductors 214 to be bonded to the exposed surfaces of the RDL 212 and to protrude out from the insulating protective layer 213. Subsequently, a temporary carrier 5 is bonded to the insulating protective layer 213 at the first side 21a via an adhesive 50, so that protruding sections of the conductors 214 are embedded in the adhesive 50. Thereafter, part of material of the second side 21b of the interposer body 21 is removed by grinding so that end surfaces of the conductive through holes 210 are flush with a surface of the second side 21b of the interposer body 21.

In one embodiment, the interposer body 21 is a semiconductor board made of such as silicon, glass, or the like. The conductive material 210b is a metal material such as copper, so that the conductive through hole 210 becomes a conductive through-silicon via (TSV).

Furthermore, the conductors 214 are copper bumps, and the temporary carrier 5 is a glass plate.

As shown in FIG. 2B, parts of the conductive materials 210b of the conductive through holes 210 on the second side 21b are removed to form a plurality of grooves S on the conductive through holes 210 on the second side 21b.

In one embodiment, the grooves S are formed by means of micro-etching or other manners.

As shown in FIG. 2C, a routing structure 22 is formed on the second side 21b of the interposer body 21 to electrically connect to the conductive through holes 210.

In one embodiment, the routing structure 22 includes at least one insulating layer 220 formed on the interposer body 21 and at least one routing layer 221 formed on the insulating layer 220, and the routing layer 221 extends into the grooves S to electrically connect to the conductive through holes 210. For example, the routing layer 221 may be formed by electroplating, coating, or other manners using an RDL process.

In addition, a plurality of conductive elements 24 are formed on an outermost side of the routing layer 221 by a patterned photoresist. For example, the conductive element 24 adopts a micro bump (u-bump) specification and includes a solder material.

As shown in FIG. 2D, the temporary carrier 5 and the adhesive 50 are removed, and a singulation process is performed along cutting paths L as shown in FIG. 2C to obtain a plurality of interposers 2a.

As shown in FIG. 2E, a carrier 9 is provided. A circuit portion 20 is formed on the carrier 9 for the interposer 2a to be disposed on the circuit portion 20 using its second side 21b so that the conductive elements 24 are electrically connected to the circuit portion 20.

In one embodiment, the carrier 9 is, for example, a board made of semiconductor material (e.g., silicon or glass), on which a release layer 90 and a seed layer 91 (e.g., made of titanium/copper) are formed sequentially, e.g., by coating, for the circuit portion 20 to be formed on the carrier 9 by a patterning process.

Furthermore, the circuit portion 20 has a coreless specification and includes a first dielectric layer 200 and a first circuit layer 201 formed on the first dielectric layer 200 and electrically connected to the conductive elements 24, such as a redistribution layer (RDL) specification. For example, a material forming the first circuit layer 201 is copper, and a material forming the first dielectric layer 200 is polybenzoxazole (PBO), polyimide (PI), prepreg (PP), or other dielectric materials.

In addition, a plurality of conductive pillars 23 for electrically connecting the circuit portion 20 are formed on the circuit portion 20. For example, the conductive pillar 23 may be made of, but is not limited to, a metal material such as copper or a solder material.

As shown in FIG. 2F-1, an encapsulation layer 25 is formed on the circuit portion 20 on the carrier 9 to cover the interposer 2a and the plurality of conductive pillars 23, and includes a first surface 25a and a second surface 25b opposing the first surface 25a. Further, end surfaces of the conductive pillars 23 and end surfaces of protruding sections of the conductors 214 are exposed out from the first surface 25a of the encapsulation layer 25, and the encapsulation layer 25 is bonded to the circuit portion 20 via the second surface 25b thereof.

In one embodiment, the encapsulation layer 25 is made of an insulating material, such as polyimide (PI), a dry film, or an encapsulant or a molding compound such as epoxy (epoxy resin). The encapsulation layer 25 is formed on the circuit portion 20 by a process, such as liquid compound, injection, lamination, compression molding, or other manners.

Moreover, the first surface 25a of the encapsulation layer 25 can be made flush with the end surfaces of the conductive pillars 23 and the end surfaces of the conductors 214 via a leveling process, so that the conductive pillars 23 and the conductors 214 are exposed out from the first surface 25a of the encapsulation layer 25. For example, the leveling process removes parts of materials from the conductors 214, the encapsulation layer 25, and the conductive pillars 23 via grinding.

Alternatively, as shown in FIG. 2F-2, a dielectric material 215 such as PI may be formed to cover the protruding sections of the conductors 214 (the formation of the dielectric material 215 may be in the process shown in FIG. 2A or FIG. 2D), and then the encapsulation layer 25 covers the interposer 2a, and a leveling process is performed.

As shown in FIG. 2G, a circuit structure 26 is formed on the first surface 25a of the encapsulation layer 25 to electrically connect to the conductive pillars 23 and the conductors 214 on the interposer 2a.

In one embodiment, the circuit structure 26 includes a plurality of second dielectric layers 260 formed on the first surface 25a and a plurality of second circuit layers 261 formed on the second dielectric layers 260, such as a redistribution layer (RDL) specification, and the second circuit layers 261 are electrically connected to the conductive pillars 23 and the conductors 214.

In addition, an outermost second dielectric layer 260 may be used as a solder-resist layer, such that an outermost second circuit layer 261 is exposed out from the solder-resist layer for severing as electrical contact pads 262. Or, the circuit structure 26 may include a single second dielectric layer 260 and a single second circuit layer 261.

Furthermore, a material forming the second circuit layer 261 is copper, and a material forming the second dielectric layer 260 is a dielectric material such as polybenzoxazole (PBO), polyimide (PI), or prepreg (PP), or a solder-resist material such as solder mask (e.g., green solder mask) or graphite (e.g., ink). It should be understood that materials for the first dielectric layer 200 and the second dielectric layer 260 may be the same or different.

As shown in FIG. 2H, at least one electronic component 28 is disposed on the circuit structure 26, and a packaging layer 27 covers the electronic component 28.

The electronic component 28 is, for example, an active component, a passive component, a package structure, or a combination thereof. The active component is, for example, a semiconductor chip, and the passive component is, for example, a resistor, a capacitor, or an inductor.

In one embodiment, the electronic component 28 is a semiconductor chip. The electronic component 28 can be disposed on the electrical contact pads 262 of the circuit structure 26 in a flip-chip manner via a plurality of conductive bumps 280, such as solder bumps, copper bumps, or others, and is electrically connected to the second circuit layer 261, and the conductive bumps 280 can be covered with an underfill 281; or, the electronic component 28 can be electrically connected to the second circuit layer 261 in a wire-bonding manner via a plurality of bonding wires; alternatively, the electronic component 28 can directly contact the second circuit layer 261. It should be understood that there are many ways for the electronic component 28 to be electrically connected to the circuit structure 26, and are not limited to the above.

Furthermore, the packaging layer 27 is made of an insulating material, such as polyimide (PI), a dry film, or an encapsulant or a molding compound such as epoxy (epoxy resin). The packaging layer 27 is formed on the circuit structure 26 by a process, such as liquid compound, injection, lamination, compression molding, or other manners. It should be understood that materials for the packaging layer 27 and the encapsulation layer 25 may be the same or different.

As shown in FIG. 21, the carrier 9 and the release layer 90 and the seed layer 91 thereon are removed to expose the circuit portion 20.

In one embodiment, parts of surfaces of the first circuit layer 201 are exposed out from the first dielectric layer 200 so that a plurality of conductive bumps 29 made of solder materials and having, for example, a C4 specification are formed on the exposed surfaces of the first circuit layer 201, such that in a subsequent process, the electronic package 2 can be attached to an electronic device (not shown), such as a circuit board, via the conductive bumps 29.

Moreover, the packaging layer 27 may be ground so that a surface of the packaging layer 27 is flush with a surface of the electronic component 28, with the electronic component 28 exposed.

Therefore, the manufacturing method of the interposer 2a of the present disclosure mainly involves forming the grooves S on the conductive through holes 210 to form the routing structure 22 directly on the grooves S and the second side 21b of the interposer body 21, so that a passivation layer does not need to be formed on the second side 21b of the interposer body 21, thus obviating the CVD process and CMP process. Accordingly, in comparison to the prior art, the electronic package 2 of the present disclosure can effectively simplify the manufacturing process and save a lot of manufacturing time and material costs (such as passivation materials), thereby significantly reducing the manufacturing cost.

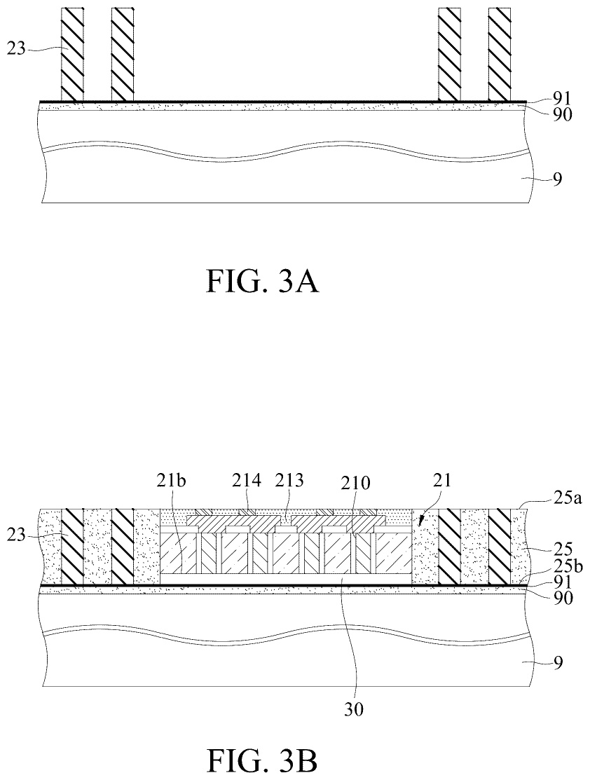

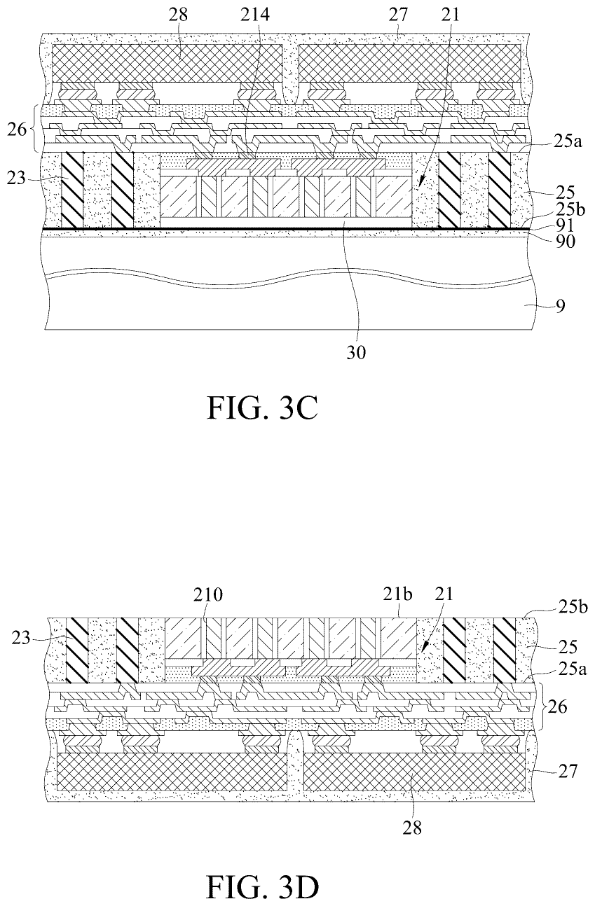

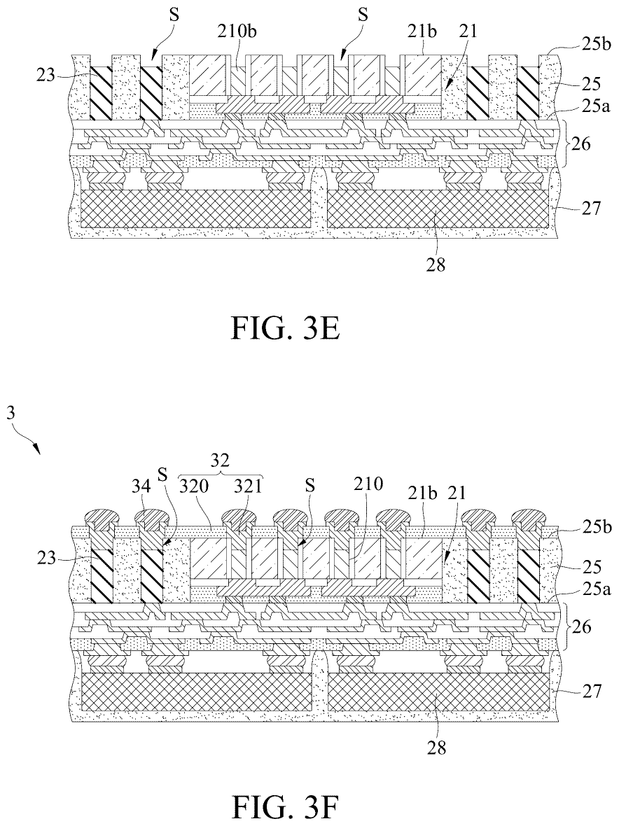

FIG. 3A to FIG. 3F are schematic cross-sectional views illustrating a manufacturing method of an electronic package 3 according to the second embodiment of the present disclosure. The difference between the second embodiment and the first embodiment lies in the manufacturing sequence of the grooves. The other structures are generally the same, and thus a detailed repetition of these similarities is unnecessary.

As shown in FIG. 3A, a carrier 9 is provided, and a plurality of conductive pillars 23 are formed by means of a seed layer 91 on a release layer 90 of the carrier 9.

As shown in FIG. 3B, at least one interposer body 21 shown in FIG. 2A is performed with a singulation process and then is disposed on the carrier 9 via the second side 21b thereof. Then, an encapsulation layer 25 is formed on the carrier 9 to cover the interposer body 21 and the conductive pillars 23, and the first surface 25a of the encapsulation layer 25 is flush with the end surfaces of the conductive pillars 23 and the end surfaces of the conductors 214, so that the conductive pillars 23 and the conductors 214 are exposed out from the first surface 25a of the encapsulation layer 25.

In one embodiment, the interposer body 21 is adhered onto the seed layer 91 via a bonding layer 30, such as an adhesive.

As shown in FIG. 3C, a circuit structure 26 is formed on the first surface 25a of the encapsulation layer 25 to electrically connect to the conductive pillars 23 and the conductors 214 on the interposer body 21. Then, at least one electronic component 28 is disposed on the circuit structure 26, and then the electronic component 28 is covered by a packaging layer 27.

As shown in FIG. 3D, the carrier 9 and the release layer 90 and the seed layer 91 thereon are removed to expose the second surface 25b of the encapsulation layer 25, and the bonding layer 30 is removed to expose the second side 21b of the interposer body 21.

In one embodiment, end surfaces of the conductive through holes 210 and end surfaces of the conductive pillars 23 are exposed out from the second surface 25b of the encapsulation layer 25.

As shown in FIG. 3E, parts of the conductive materials 210b of the conductive through holes 210 and parts of materials of the conductive pillars 23 are removed to form a plurality of grooves S on the conductive through holes 210 and the conductive pillars 23.

In one embodiment, the grooves S are formed by means of micro-etching or other manners.

As shown in FIG. 3F, a routing structure 32 is formed on the second side 21b of the interposer body 21 and the second surface 25b of the encapsulation layer 25 to electrically connect to the conductive through holes 210 and the conductive pillars 23.

In one embodiment, the routing structure 32 includes an insulating layer 320 formed on the interposer body 21 and the encapsulation layer 25 and a routing layer 321 formed on the insulating layer 320, and the routing layer 321 extends into the grooves S to electrically connect to the conductive through holes 210 and the conductive pillars 23. For example, the routing layer 321 may be formed by electroplating, coating, or other manners using an RDL process.

In addition, a plurality of conductive elements 34 are formed on an outermost side of the routing layer 321 by a patterned photoresist, such that in a subsequent process, the electronic package 3 can be attached to an electronic device (not shown), such as a circuit board, via the conductive elements 34.

Therefore, the manufacturing method of the present disclosure involves forming grooves S on the conductive through holes 210 to form the routing structure 32 directly on the grooves S and the second side 21b of the interposer body 21, so that a passivation layer does not need to be formed, thus obviating the CVD process and CMP process. Accordingly, in comparison to the prior art, the electronic package 3 of the present disclosure can effectively simplify the manufacturing process and save a lot of manufacturing time and material costs (such as passivation materials), thereby significantly reducing the manufacturing cost.

The present disclosure also provides an interposer 2a, which comprises: an interposer body 21 and a routing structure 22, 32.

The interposer body 21 has a first side 21a and a second side 21b opposing the first side 21a, and the interposer body 21 is formed with a plurality of conductive through holes 210 therein, and the second side 21b of the interposer body 21 is formed with a plurality of grooves S thereon corresponding to the plurality of conductive through holes 210.

The routing structure 22, 32 is disposed on the second side 21b of the interposer body 21 and extends into the plurality of grooves S to electrically connect to the plurality of conductive through holes 210.

The interposer 2a further comprises a redistribution layer (RDL) 212 formed on the first side 21a of the interposer body 21 and electrically connected to the plurality of conductive through holes 210.

The present disclosure also provides an electronic package 2, 3, which comprises: the interposer 2a, a circuit structure 26, and at least one electronic component 28.

The circuit structure 26 is formed on the first side 21a of the interposer body 21 and electrically connected to the conductive through holes 210.

The electronic component 28 is disposed on and electrically connected to the circuit structure 26.

In one embodiment, the electronic package 2, 3 further comprises an encapsulation layer 25 covering the interposer body 21 and the routing structure 22, 32, and the encapsulation layer 25 has a first surface 25a and a second surface 25b opposing the first surface 25a, and the circuit structure 26 is disposed on the first surface 25a of the encapsulation layer 25.

In one embodiment, the electronic package 2 further comprises a circuit portion 20 formed on the second surface 25b of the encapsulation layer 25 to electrically connect to the routing structure 22 via a plurality of conductive elements 24. For example, the circuit portion 20 is bonded with a plurality of conductive bumps 29.

In one embodiment, the electronic package 2, 3 further comprises a plurality of conductive pillars 23 formed in the encapsulation layer 25 and electrically connected to the circuit structure 26. For instance, further grooves S are formed on the plurality of conductive pillars 23, and the routing structure 32 extends into the further grooves S to electrically connect to the plurality of conductive pillars 23.

In one embodiment, a plurality of conductive elements 24, 34 are bonded on the routing structure 22, 32.

To sum up, the electronic package and manufacturing method thereof and

interposer involves the formation of grooves, a passivation layer does not need to be formed on the second side of the interposer body, thus obviating the CVD process and CMP process. Accordingly, the present disclosure can effectively simplify the manufacturing process and save a lot of manufacturing time and material costs, thereby significantly reducing the manufacturing cost.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. An interposer, comprising:
an interposer body having a first side, a second side opposing the first side, a plurality of conductive through holes formed in the interposer body, and a plurality of grooves formed on the second side of the interposer body and corresponding to the plurality of conductive through holes; and
a routing structure disposed on the second side of the interposer body, extending into the plurality of grooves, and electrically connected to the plurality of conductive through holes.

2. The interposer of claim 1, further comprising a redistribution layer formed on the first side of the interposer body and electrically connected to the plurality of conductive through holes.

3. An electronic package, comprising:
an interposer body having a first side, a second side opposing the first side, a plurality of conductive through holes formed in the interposer body, and a plurality of grooves formed on the second side of the interposer body and corresponding to the plurality of conductive through holes;
a routing structure disposed on the second side of the interposer body, extending into the plurality of grooves, and electrically connected to the plurality of conductive through holes;
a circuit structure disposed on the first side of the interposer body and electrically connected to the plurality of conductive through holes; and
an electronic component disposed on and electrically connected to the circuit structure.

4. The electronic package of claim 3, further comprising an encapsulation layer covering the interposer body and having a first surface and a second surface opposing the first surface, wherein the circuit structure is disposed on the first surface of the encapsulation layer.

5. The electronic package of claim 4, further comprising a circuit portion disposed on the second surface of the encapsulation layer and electrically connected to the plurality of conductive through holes.

6. The electronic package of claim 5, wherein the circuit portion is bonded with a plurality of conductive bumps.

7. The electronic package of claim 4, further comprising a plurality of conductive pillars formed in the encapsulation layer and electrically connected to the circuit structure.

8. The electronic package of claim 7, wherein the plurality of conductive pillars are formed with further grooves, and the routing structure extends to the further grooves to electrically connect to the plurality of conductive pillars.

9. The electronic package of claim 5, wherein the routing structure is bonded with a plurality of conductive elements.

10. The electronic package of claim 8, wherein the routing structure is bonded with a plurality of conductive elements.

11. The electronic package of claim 3, further comprising a redistribution layer formed on the first side of the interposer body and electrically connected to the plurality of conductive through holes.

12. A method of manufacturing an electronic package, the method comprising:
providing an interposer body having a first side, a second side opposing the first side, and a plurality of conductive through holes formed in the interposer body;
forming a plurality of grooves on the second side of the interposer body and corresponding to the plurality of conductive through holes;
forming a routing structure on the second side of the interposer body in a manner that the routing structure extends into the plurality of grooves and is electrically connected to the plurality of conductive through holes; and
disposing the interposer body on a circuit portion with a plurality of conductive pillars via the second side thereof, and electrically connecting the routing structure to the circuit portion via a plurality of conductive elements.

13. The method of claim 12, further comprising forming an encapsulation layer on the circuit portion to cover the interposer body and the routing structure, and forming a circuit structure on the encapsulation layer and the first side of the interposer body to be electrically connected to the plurality of conductive through holes.

14. The method of claim 13, further comprising disposing an electronic component on the circuit structure and electrically connecting the electronic component to the circuit structure.

15. The method of claim 14, further comprising forming a plurality of conductive bumps on the circuit portion.

16. The method of claim 12, wherein the first side of the interposer body is formed with a redistribution layer electrically connected to the plurality of conductive through holes.

17. A method of manufacturing an electronic package, the method comprising:
providing an interposer body having a first side, a second side opposing the first side, and a plurality of conductive through holes formed in the interposer body;
forming a circuit structure on the first side of the interposer body to be electrically connected to the plurality of conductive through holes;
disposing an electronic component on the circuit structure and electrically connecting the electronic component to the circuit structure;
forming a plurality of grooves on the second side of the interposer body and corresponding to the plurality of conductive through holes; and
forming a routing structure on the second side of the interposer body in a manner that the routing structure extends into the plurality of grooves and is electrically connected to the plurality of conductive through holes.

18. The method of claim 17, further comprising forming an encapsulation layer to cover the interposer body, and forming the circuit structure on the encapsulation layer and the first side of the interposer body.

19. The method of claim 18, further comprising forming a plurality of conductive pillars in the encapsulation layer and electrically connecting the plurality of conductive pillars to the circuit structure.

20. The method of claim 19, wherein the plurality of conductive pillars are formed with further grooves, and the routing structure extends to the further grooves to electrically connect to the plurality of conductive pillars.

21. The method of claim 17, wherein the routing structure is bonded with a plurality of conductive elements.

22. The method of claim 17, wherein the first side of the interposer body is formed with a redistribution layer electrically connected to the plurality of conductive through holes.
